(19) United States
(12) Patent Application Publication
(10) Pub. No.: US 2015/0333197 A1
(43) Pub. Date: Nov. 19, 2015

(54) METHOD OF MANUFACTURING A SOLAR CELL ELECTRODE

(71) Applicant: E I DU PONT DE NEMOURS AND COMPANY, Wilmington, DE (US)

(72) Inventors: NORIHIKO TAKEDA, KAWASAKI (JP); KAZUSHIGE ITO, KAWASAKI (JP)

(21) Appl. No.: 14/681,326

(22) Filed: Apr. 8, 2015

Related U.S. Application Data
(60) Provisional application No. 61/992,381, filed on May 13, 2014.

(51) Int. Cl. H01L 31/0224; H01L 31/18

(52) U.S. Cl. CPC H01L 31/022425; H01L 31/1864; H01L 31/1868

(57) ABSTRACT

A method of manufacturing a solar cell electrode comprising steps of: preparing an N-type solar cell substrate, wherein the N-type solar cell substrate comprises an n-doped semiconductor substrate, a p-type emitter formed on one side of the semiconductor substrate, and a passivation layer formed on the p-type emitter; stencil printing a conductive paste onto the passivation layer through a printing mask, the conductive paste comprising, (i) 60 to 95 wt % of a conductive powder, (ii) 0.4 to 3.0 wt % of an aluminum powder, (iii) 0.1 to 10 wt % of a glass frit, (iv) 3 to 30 wt % of an organic medium, (v) 0.4 to 1.7 wt % of an amide compound, based on the total weight of the conductive paste; and firing the applied conductive paste to form a solar cell electrode in electric contact with the p-type emitter.

### FIELD OF THE INVENTION

This invention relates to solar cell electrodes and, in particular, relates to solar cell electrodes formed on an N-type substrate.

### TECHNICAL BACKGROUND OF THE INVENTION

Generally, in order to increase the power generation characteristics of the solar cell, the characteristic of the conversion efficiency EFF (%) is a particularly important factor among the factors determining the efficiency of a solar cell. In order to achieve this objective, a variety of solar cell manufacturing techniques for fabricating electrodes having a high-aspect ratio have been proposed. For example, a process for forming solar cell electrodes having a high aspect ratio, which attains superior conversion efficiency EFF (%) by screen-printing a conductive paste containing carbon fibers, have been proposed in US-2010-0294353 A1.

### SUMMARY OF THE INVENTION

In one aspect, the present invention relates to a method of manufacturing a solar cell electrode comprising the steps of: preparing an N-type solar cell substrate, wherein the N-type solar cell substrate comprises an n-doped semiconductor substrate, a p-type emitter formed on one side of the semiconductor substrate, and a passivation layer formed on the p-type emitter; stencil printing a conductive paste onto the passivation layer through a printing mask, the conductive paste comprising, (i) 60 wt % to 95 wt % of a conductive powder, (ii) 0.4 wt % to 3.0 wt % of an aluminum powder, (iii) 0.1 wt % to 10 wt % of a glass frit, (iv) 3 wt % to 30 wt % of an organic medium, (v) 0.4 wt % to 1.7 wt % of an amide compound, wherein the wt % are based on the total weight of the conductive paste; and firing the applied conductive paste to form a solar cell electrode in electric contact with the p-type emitter.

In another aspect, the present invention relates to a solar cell electrode manufactured by the method.

The aspect ratio (height/width) and electrical resistance of the electrodes of N-type solar cells can be improved by the present invention. Thus, a solar cell with an excellent photoelectric conversion efficiency (efficiency (%)) is efficiently provided according to the present invention.

### BRIEF DESCRIPTION OF THE DRAWINGS

FIG. 1 shows a manufacturing process of a p-type electrode of an N-type solar cell.

FIG. 2 is a schematic drawing showing a metal mask which can be used in the present invention.

### DETAILED DESCRIPTION OF THE INVENTION

The following shows an embodiment of the manufacturing process of solar cell electrodes. However, the invention is not limited to the following embodiment. It should be understood that although the present invention has been specifically disclosed by preferred embodiments and optional features, modification, improvement and variation of the inventions herein disclosed may be resorted to by those skilled in the art, and that such modifications, improvements and variations are considered to be within the scope of this invention. In addition, pending U.S. patent applications (ex. Ser. No. 13/906,381 filed on May 31, 2013), patent publications (ex. US-2010-0294353), patent applications, issued patents, and other documents referred to in this specification are herein incorporated by reference as if each individual publication.

Method of Manufacturing a p-Type Electrode

An N-type solar cell substrate comprising an n-doped semiconductor substrate (n-base layer) 10 and a p-type emitter 20 is prepared.

The n-base layer can be defined as a semiconductor layer containing an impurity called donor dopant where the donor dopant introduces extra valence electrons in the semiconductor element. In the n-base layer, free electrons are generated from the donor dopant in the conduction band.

By adding an impurity to an intrinsic semiconductor as above, electrical conductivity can be varied not only by the number of impurity atoms but also, by the type of impurity atom and the changes can be a thousand fold and a million fold.

The n-base layer 10 can be formed by doping a silicon wafer with a donor impurity such as phosphorus.

The p-type emitter 20 can be defined as a semiconductor layer containing an impurity called acceptor dopant where the acceptor dopant introduces deficiency of valence electrons in the semiconductor element. In the p-type emitter, the acceptor dopant takes in free electrons from semiconductor element and consequently positively charged holes are generated in the valence band.

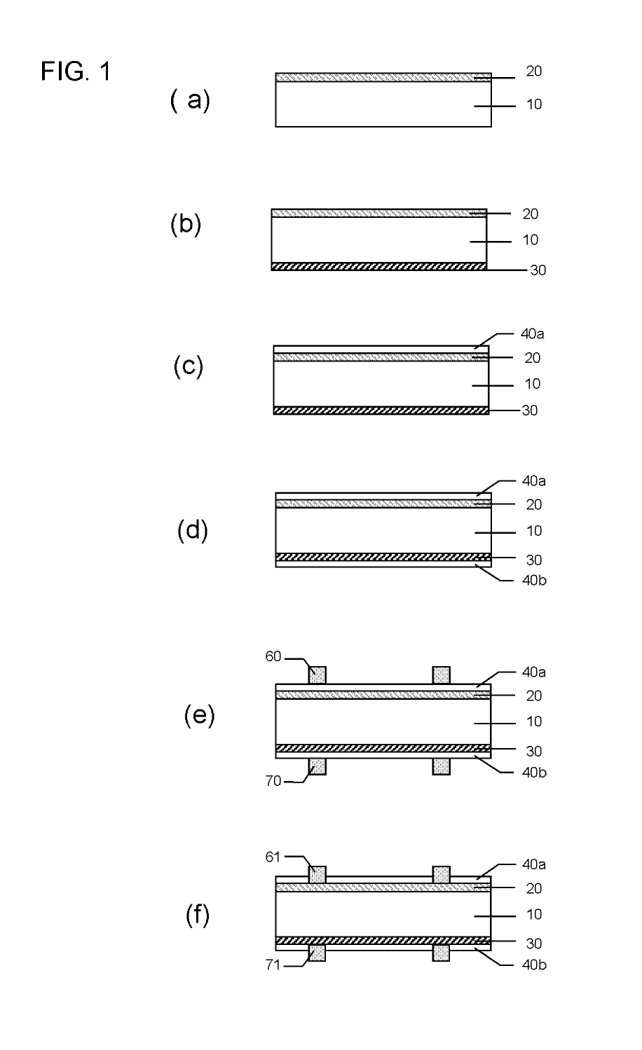

The p-type emitter 20 can be formed, for example, by thermal diffusion of an acceptor dopant into the N-type semiconductor substrate (FIG. 1(a)). The acceptor dopant source can be a boron compound such as boron tribromide (BBr₃). The thickness of the p-type emitter can be, for example, 0.1 to 10% of the N-type semiconductor substrate thickness.

Then an n⁺-layer 30 can be formed at the other side of the p-type emitter 20 (FIG. 1(b)), although it is not essential. The n⁺-layer 30 contains the donor impurity with higher concentration than that in the n-base layer 10. For example, the n⁺-layer 30 can be formed by thermal diffusion of phosphorus in the case of silicon semiconductor using phosphorus oxychloride (POCl₃) as a dopant source. By forming the n⁺-layer 30, the recombination of electrons and holes at the border of the n-base layer 10 and the n⁺-layer 30 can be reduced.

A first passivation layer 40a can be formed on the p-type emitter 20 (FIG. 1(c)). The first passivation layer 40a can be 10 to 2000 Å thick. Silicon nitride (SiNₓ), amorphous silicon (a-Si), silicon carbide (SiCₓ), Titanium oxide (TiOₓ), Aluminum oxide (AlOₓ) Silicon oxide (SiOₓ), Indium Tin Oxide (ITO), or a mixture thereof can be used as a material of the passivation layer 40. The first passivation layer 40a can be formed by, for example, plasma enhanced chemical vapor deposition (PECVD) of these materials.

When the n⁺-layer 30 is formed, the N-type semiconductor substrate comprises the n⁺-layer between the n-base layer 10 and a passivation layer 40 which is formed in the next step.

A second passivation layer 40b is formed on the n⁺-layer 30 (FIG. 1(d)). The material and forming method of the second passivation layer 40b can be the same as those for the first passivation layer 40a. However, the second passivation layer 40b on the n⁺-layer 30 can be different from the first passivation layer 40a in terms of its forming material, its thickness, or its forming method.

When the N-type solar cell is illuminated by sunlight in the operation of the solar cell, the passivation layer(s) 40a and; or 40b reduces the carrier recombination at the surface, and also reduces optical reflection losses so that it is also called an anti-reflection coating (“ARC”). In one embodiment, both sides of n-base layer 10 and p-type emitter 20 can be light receiving sides in the operation (bifacial cell). In another embodiment, the first passivation layer 40a is formed on the sun-light receiving side (front side) and the second passivation layer 40b is formed on the rear side. In another embodiment, the second passivation layer 40b is formed on the sun-light receiving side and the first passivation layer 40a is formed on the rear side.

A conductive paste 60 for forming p-type electrodes is applied by stencil printing onto the first passivation layer 40a formed on the p-type emitter 20 (FIG. 1(e)) and then dried. The stencil printing is described later in more detail. The conductive paste 70 for forming an n-type electrode is also applied onto the second passivation layers 40b on the n⁺-layer 30. When applying the conductive pastes 70, screen printing, stencil printing or nozzle printing is used in an embodiment.

In one embodiment, the conductive paste 70 on the second passivation layer 40b can be different in composition from the conductive paste 60 on the first passivation layer 40a. The composition of the conductive paste 70 can be adjusted depending on, for example, the doping profile of n⁺ layer, material or thickness of the second passivation layer 40b.

In another embodiment, the conductive paste 60 applied on the p-type emitter 20 and the conductive paste 70 applied on the n⁺-layer 30 are the same in composition. In one embodiment, both conductive paste 60 and 70 are applied by stencil printing. In another embodiment, conductive paste 60 is applied by stencil printing while conductive paste 70 is applied by another printing method such as screen printing. The conductive pastes 60 and 70 are dried for 10 seconds to 10 minutes at 50-200° C. in an embodiment.

Firing of the conductive pastes is then carried out. The conductive pastes 60 and 70 fire through the passivation layers 40a and 40b during the firing process in a way that a p-type electrode 61 and an n-type electrode 71 have good electrical connection with the p-type emitter 20 and the n⁺-layer 30 respectively (FIG. 1(f)). When the connections between these electrodes and semiconductor are improved, the electrical properties of a solar cell will also be improved.

An infrared furnace can be used for the firing process Firing conditions can be controlled in consideration of firing temperature and firing time. The firing peak temperature can be 700° C. to 800° C. In one embodiment. The firing time from an entrance to an exit of a furnace can be from 30 seconds to 5 minutes, in another embodiment 40 seconds to 3 minutes.

In another embodiment, firing profile is 10 to 60 seconds at over 400° C. and 2 to 10 seconds at over 600° C. The firing temperature is measured at the upper surface of the semiconductor substrate. With the firing temperature and time inside the specified range, less damage occurs to the semiconductor substrate during firing.

The process of stencil printing is described in more details below.

A conductive paste is applied by stencil printing onto the passivation layer through a printing mask. The conductive paste to form a p-type electrode comprises a conductive powder, an aluminum powder, a glass frit, an organic medium and an amide compound.

(i) Conducting Powder

The conductive powder is any powder that enables to transport electrical current. The conductive powder comprises a metal selected from the group consisting of silver (Ag), copper (Cu), nickel (Ni) and a mixture thereof in an embodiment. In one embodiment, the conductive powder is a metal powder selected from the group consisting of Ag powder, Cu powder, Ni powder, alloy powder containing Ag, Cu or Ni and a mixture thereof. Using such conductive powder with relatively high electrical conductivity, resistive power loss of a solar cell can be minimized. In one embodiment, a conductive powder can be Ag powder. Ag powder sinters and does not form oxides after firing in air and provides highly conductive bulk material.

The conductive powder is 60 to 95 weight percent (wt %) in an embodiment, 70 to 92 wt % in another embodiment, and 80 to 90 wt % in another embodiment, based on the total weight of the conductive paste. A conductive powder with such amount in the conductive paste can retain sufficient conductivity for solar cell applications.

In one embodiment, the conductive powder can be flaky or spherical in its shape.

The particle diameter is 0.1 to 10 μm in an embodiment, 0.5 to 7 μm in another embodiment, and 1 to 4 μm in another embodiment. The conductive powder with such particle diameter can be adequately dispersed in the organic binder and solvent, and smoothly applied by stencil printing. In one embodiment, the conductive powder can be a mixture of two or more of conductive powders with different particle diameters.

The particle diameter is obtained by measuring the distribution of the particle diameters by using a laser diffraction scattering method and can be defined as D50. Microtrac model X-100 is an example of the commercially-available devices.

In one embodiment, the conductive powder can be of high purity of 99% or higher. However, depending on the electrical requirements of the electrode pattern, less pure silver can also be used.

(ii) Aluminum Powder

Aluminum (Al) powder is a metal powder containing at least Al. The purity of the Al powder is 98% or higher in an embodiment, and 99% or higher in another embodiment. The content of the Al powder is 0.4 to 3 wt % in an embodiment, 0.5 to 2 wt % in another embodiment, and 0.6 to 1.6 wt % in another embodiment, based on the total weight of the conductive paste. By adding the Al powder with such amount in the conductive paste can reduce the contact resistance and improve the electrical properties of a solar cell.

The particle diameter (D50) of the Al powder is 2.6 to 11 μm in an embodiment. The particle diameter (D50) of the Al powder is not smaller than 2.8 μm in an embodiment, and not smaller than 3.0 μm in another embodiment. The upper limit of the particle diameter is 8 μm or smaller in an embodiment, 6 μm or smaller in another embodiment, and 5 μm or smaller in another embodiment. With such particle diameter of Al powder, electrical properties of a solar cell can be improved. In addition, the aluminum powder with such particle diameter can be dispersed well in the organic medium and appropriate to be applied on a substrate by stencil printing. To measure the particle diameter (D50) of the Al powder, the same method as used for the conductive powder can be applied.

In one embodiment, the Al powder can be flaky, nodular, or spherical in its shape. The nodular powder is irregular particles with knotted, rounded shapes. In another embodiment, Al powder can be spherical.

(iii) Glass Frit

Glass frits help to form an electrical contact through the passivation layer during the consequent firing process and facilitate binding of the electrode to the semiconductor substrate. The glass frits may also promote sintering of the conductive powder.

The content of the glass frit can be 0.1 wt % to 10 wt %, based on the total weight of the conductive paste. The content is 1 wt % to 9 wt % in another embodiment, and 2 wt % to 8 wt % in another embodiment, based on the total weight of the conductive paste in another embodiment. By adding glass frit with such amount, the p-type electrode can sufficiently adhere to a substrate.

The glass frit composition is not limited to specific compositions. A lead-free glass or a lead containing glass can be used, for example.

In one embodiment, the glass frit comprises a lead containing glass frit containing lead oxide and one or more of oxides selected from a group consisting of silicon oxide (SiO₂), boron oxide (B₂O₃) and aluminum oxide (Al₂O₃).

Lead oxide (PbO) is 40 to 80 mol % in an embodiment, and 42 to 73 mol % in another embodiment, and 45 to 68 mol % in another embodiment based on the total molar fraction of each component in the glass frit.

Silicon oxide (SiO₂) is 0.5 to 40 mol % in an embodiment, 1 to 33 mol % in another embodiment, and 1.3 to 28 mol % in another embodiment, based on the total molar fraction of each component in the glass frit.

Boron oxide (B₂O₃) is 15 to 48 mol % in an embodiment, 20 to 43 mol % in another embodiment, and 22 to 40 mol % in another embodiment, based on the total molar fraction of each component in the glass frit.

Aluminum oxide (Al₂O₃) is 0.01 to 6 mol % in an embodiment, 0.09 to 4.8 mol % in another embodiment, and 0.5 to 3 mol % in another embodiment, based on the total molar fraction of each component in the glass frit.

In another embodiment, the glass frit comprises a lead-free glass frit not containing lead oxide (PbO) and containing one or more of oxides selected from the group consisting of boron oxide (B₂O₃), zinc oxide (ZnO), bismuth oxide (Bi₂O₃), silicon oxide (SiO₂), aluminum oxide (Al₂O₃), alkaline-earth metal oxide, and alkali metal oxide.

Boron oxide (B₂O₃) is 20 to 48 mol % in an embodiment, 25 to 42 mol % in another embodiment, and 28 to 39 mol % in another embodiment, based on the total molar fraction of each component in the glass frit.

Zinc oxide (ZnO) is 15 to 45 mol % in an embodiment, 25 to 38 mol % in another embodiment, and 28 to 36 mol % in another embodiment, based on the total molar fraction of each component in the glass frit.

Bismuth oxide (Bi₂O₃) is 15 to 40 mol % in an embodiment, 18 to 35 mol % in another embodiment, and 19 to 30 mol % in another embodiment based on the total molar fraction of each component in the glass frit.

Silicon oxide (SiO₂) is 0.5 to 20 mol % in an embodiment, 0.9 to 6 mol % in another embodiment, and 1 to 3 mol % in another embodiment, based on the total molar fraction of each component in the glass frit.

Aluminum oxide (Al₂O₃) is 0.9 to 8 mol % in an embodiment, 2.5 to 7.5 mol % in another embodiment, 3 to 7.3 mol % in still further embodiment, based on the total molar fraction of each component in the glass frit.

The alkaline-earth metal oxide is a general term for the group consisting of beryllium oxide (BeO), magnesium oxide (MgO), calcium oxide (CaO), strontium oxide (SrO) and barium oxide (BaO). The alkaline-earth metal oxide is BaO, CaO, MgO or a mixture thereof in an embodiment, and BaO, CaO or a mixture thereof in another embodiment. The alkaline-earth metal oxide is 0.5 to 20 mol % in an embodiment, 0.9 to 8 mol % in another embodiment, 1 to 7.5 mol % in still another embodiment, based on the total molar fraction of each component in the glass frit.

The alkali metal oxide is a general term for the group consisting of lithium oxide (Li₂O), sodium oxide (Na₂O), potassium oxide (K₂O), rubidium (Rb₂O) and cesium oxide (Cs₂O). The alkali metal oxide can be Li₂O in an embodiment. The alkaline metal oxide is 0.5 to 20 mol % in an embodiment, 0.9 to 8 mol % in another embodiment, and 1 to 7.5 mol % in still another embodiment, based on the total molar fraction of each component in the glass frit.

The softening point of the glass frits is 300 to 600° C. in an embodiment, and 350 to 550° C. in another embodiment. In this specification, “softening point” is determined by differential thermal analysis (DTA). To determine the glass softening point by DTA, sample glass is ground and is introduced with a reference material into a furnace to be heated at a constant rate of 5 to 20° C. per minute. The difference in temperature between the two is detected to investigate the evolution and absorption of heat from the material. The glass softening point (Ts) can be determined by the temperature at the third inflection point in the DTA curve.

Glass frit can be prepared by methods well known in the art. For example, the glass component can be prepared by mixing and melting raw materials such as oxides, hydroxides, carbonates, making into a cullet by quenching, followed by mechanical pulverization (wet or dry milling). Thereafter, if needed, classification is carried out to the desired particle size.

(iv) Organic Medium

The conductive paste comprises an organic medium, which comprises organic binder and solvent.

In one embodiment, the organic binder can comprise ethyl cellulose, ethylhydroxyethyl cellulose, Foralyn™ (pentaerythritol ester of hydrogenated rosin), dammar gum, wood rosin, phenolic resin, acryl resin, polymethacrylate of lower alcohol or a mixture thereof.

In one embodiment, the solvent can comprise terpenes such as alpha- or beta-terpineol or mixtures thereof, Texanol™. (2,2,4-trimethy-1,3-pentanediolmonoisobutyrate), kerosene, dibutylphthalate, butyl Carbitol™, butyl Carbitol™ acetate, hexylene glycol, monobutyl ether of ethylene glycol monoacetate, diethylene glycol monobutyl ether, diethylene 1.0 glycol monobutyl ether acetate, diethylene glycol dibutyl esther, bis(2-(2-butoxyethoxyl)ethyl) adipate, dibasic esters such as DBE®, DBE®-2, DBE®-3, DBE®-4, DBE®-5, DBE®-6, DBE®-9, and DBE®-1B from Invista, octyl epoxy tallate, isotetradecanol, and petroleum naphtha, or a mixture thereof.

The amount of organic medium is 3 to 30 wt % in one embodiment, 5 to 25 wt % in another embodiment, 7 to 23 wt % in further embodiment, based on the total weight of the conductive paste.

The content of the organic medium is 3 to 30 wt % based on the total weight of the conductive paste. The content is 5 to 20 wt % in another embodiment, 6 to 10 wt % in further embodiment, based on the total weight of the conductive paste.

The organic medium can be burned off during the firing step so that p-type electrode ideally contains no organic residue. However, actually, a certain amount of residue can remain in the resulting p-type electrode as long as it does not degrade the electrical properties of the p-type electrode.

(v) Amide Compound

In one embodiment, by stencil printing a conductive paste containing a given amount of an amide compound, is applied through a given metal mask by stencil printing onto the passivation layer on the p-type emitter layer of the n-type solar cell, a fineline p-type electrode which has a high aspect ratio (height/width) can be formed to make solar cells giving a high light conversion efficiency. In another embodiment, the amide compound incorporated into the paste functions as a thixotrope which adequately improves and adjusts the viscosity of the paste.

The amide compound is a compound with the functional group R₁CONR′₂ (R and R′ refer to H or organic groups).

As the amide compound, a fatty acid amide is especially preferred from the standpoint that the addition thereof even in a small amount can impart high viscosity to the paste. The fatty acid amide is defined as an amide formed from a fatty acid(s) and an amine(s).

The fatty acid amide is available as a commercial product in the form of a powder or paste. In an embodiment, use of a powdery fatty acid amide is used from the standpoint of convenience. The fatty acid amide powder is prepared by particle-size reduction with, for example, a dry-process pulverizer such as a jet mill. The particle diameter (D50) thereof can be 20 μm or smaller in one embodiment, 10 μm or smaller in another embodiment.

In one embodiment, the fatty acid amide is a fatty acid diamide represented by the formula, R′—CO—NH—R″—NH—CO—R′. The diamide is obtained by reacting a diamine with hydroxylated fatty acids in an embodiment.

R′ independently represent an aliphatic chain of a fatty acid (fatty acid without a carboxyl group). The aliphatic chain can be substituted with one or more groups such as hydroxyl group.

The aliphatic chain includes 4-28 carbon atoms in an embodiment. The fatty acids used for the fatty acid amide include the following acid in an embodiment.
Myristoleic acid (CH₃(CH₂)₃CH═CH(CR₂)₇COOH)
Palmitoleic acid (CH₃(CH₂)₅CH═CH(CH₂)₇COOH)
Sapienic acid (CH₃(CH₂)₈CH═CH(CH₂)₄COOH)
Oleic acid (CH₃(CH₂)₇CH═CH(CH₂)₇COOH)
Elaidic acid (CH₃(CH₂)₇CH═CH(CH₂)₇COOH)
Vaccenic acid (CH₃(CH₂)₅CH═CH(CH₂)₉COOH)
Linoleic acid (CH₃(CH₂)₄CH═CHCH₂CH═CH(CH₂)₇COOH)
Linoelaidic acid (CH₃(CH₂)₄CH═CHCH₂CH═CH(CH₂)₇COOH)
α-Linolenic acid (CH₃CH₂CH═CHCH₂CH═CHCH₂CH═CH(CH₂)₇COOH)
Arachidonic acid (CH₃(CH₂)₄CH═CHCH₂CH═CHCH₂CH═CHCH₂CH═CH(CH₂)₃COOH)
Eicosapentaenoic acid (CH₃CH₂CH═CHCH₂CH═CHCH₂CH═CHCH₂CH═CHCH₂CH═CH(CH₂)₃COOH)
Erucic acid (CH₃(CH₂)₇CH═CH(CH₂)₁₁COOH)
Docosahexaenoic acid (CH₃CH₂CH═CHCH₂CH═CHCH₂CH═CHCH₂CH═CHCH₂CH═CHCR₂CH═CH(CH₂)₂COOH)
Caprylic acid (CH₃(CH₂)₆COOH)
Capric acid (CH₃(CH₂)₈COOH)
Lauric acid (CH₃(CH₂)₁₀COOH)
Myristic acid (CH₃(CH₂)₁₂COOH)
Palmitic acid (CH₃(CH₂)₁₄COOH)
Stearic acid (CH₃(CH₂)₁₆COOH)
Arachidic acid (CH₃(CH₂)₁₈COOH)
Behenic acid (CH₃(CH₂)₂₀COOH)
Lignoceric acid (CH₃(CH₂)₂₂COOH)
Cerotic acid (CH₃(CH₂)₂₄COOH)

The fatty acids used for the fatty acid amide is capric acid, stearic acid, hydroxy capric acid or hydroxy stearic acid in an embodiment. In these cases, R′ in the above formula is CH₃(CH₂)₈, CH₃(CH₂)₁₆, CH₃(CHOH)(CH₂)₇, or CH₃(CHOH)(CH₂)₁₅. The place of CHOH can be anywhere in the chain.

R″ represents an alkylene group of a diamine (alkylene group without two amino groups). The alkylene part can be substituted with one or more groups.

The alkylene group includes 2-6 carbon atoms in an embodiment. The diamines used for the fatty acid amide include the following amines in an embodiment,
Ethylenediamine (1,2-diaminoethane)
1,3-Diaminopropane (propane-1,3-diamine)
Putrescine (butane-1,4-diamine)
Cadaverine (pentane-1,5-diamine)
Hexamethylenediamine (hexane-1,6-diamine)
1,2-Diaminopropane
Diphenylethylenediamine
Diaminocyclohexane
o-Xylylenediamine
m-Xylylenediamine
p-Xylylenediamine
o-Phenylenediamine
m-Phenylenediamine
p-Phenylenediamine
4,4′-Diaminobiphenyl
1,8-Diaminonaphthalene

The diamines used for the fatty acid amide is ethylenediamine in an embodiment. In this case, R″ in the above formula is CH₂CH₂.

In one embodiment, the fatty acid amide is a diamide having a general structure represented by the following formula (A).

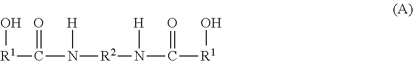

In formula (A), R¹ represents the residue formed by removing the carboxyl group from the hydroxylated fatty acid. R² represents the residue formed by removing the amino groups from the diamine. In one embodiment, a fatty acid amide represented by formula (A) where either of the R¹s located at both ends does not have the hydroxy group bonded thereto is used.

In another embodiment, examples of the fatty acid amide include a fatty acid amide having a general structure represented by the following formula (B).

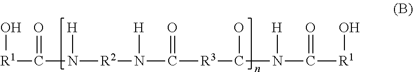

The amide compound represented by formula (B) is obtained by reacting a basic carboxylic acid, a diamine, and a hydroxylated fatty acid. In formula (B), R¹ and R² are the same as the R¹ and R² in formula (A). R³ represents a residue formed by removing carboxyl groups from the basic carboxylic acid. In one embodiment, the average degree of polymerization (n) of the amide compound represented by formula (B) is 3 to 5, and the number-average molecular weight (Mn) thereof is 1,000 to 2,000. These fatty acid amides may be used alone or in combination of two or more thereof.

The amount of the amide compound is at least 0.3 weight percent wt % in one embodiment, at least 0.4 wt % in another embodiment, at least 0.5 wt % in still another embodiment, based on the total weight of the conductive paste. The amount of the amide compound is 1.7 wt % or less in one embodiment, 1.2 wt % or less in another embodiment, and 0.9 wt % or less in still another embodiment, based on the total weight of the conductive paste.

By adding such amount of the amide compound in the conductive paste, an electrode having a high aspect ratio with narrow width and reduced line resistance can be formed on the passivation layer of the N-type solar cells to achieve high light conversion efficiency, which can be applied through a given metal mask by stencil printing.

Additives

Additives such as a thickener, a stabilizer, a dispersant, a viscosity modifier and a surfactant can be added to a conductive paste as the need arises. The amount of the additives depends on the desired characteristics of the resulting conductive paste and can be chosen by people in the industry. Multiple kinds of the additives can be added to the conductive paste.

Although components of the conductive paste were described above, the conductive paste can contain impurities coming from raw materials or contaminated during the manufacturing process. However, the presence of the impurities would be allowed (defined as benign) as long as it does not significantly alter anticipated properties of the conductive paste. For example, the p-type electrode manufactured with the conductive paste can achieve sufficient electric properties described herein, even if the conductive paste includes benign impurities.

Physical Properties of Conductive Paste

Viscosity

The viscosity of the conductive paste is 200 to 1000 Pa·s in one embodiment, 300 to 800 Pa·s in another embodiment, 350 to 700 Pa·s in further embodiment. With having such viscosity, the conductive paste has a proper value of viscosity and hence has excellent printability.

In the present invention, the viscosity of the conductive paste is a value obtained by measurement at 25° C., 10 rpm using a Brookfield HBT viscometer with a #14 spindle and a SC4-14/6R utility cup.

Inorganic Solids

The inorganic solids content of the conductive paste is calculated as the percentage (wt %) of inorganic solids relative to the total weight of the conductive paste. The inorganic solids typically consist of conductive powders and glass frit. In one embodiment, the inorganic solids content is 68.5 to 96.7 wt %, and 85 to 94 wt % in another embodiment.

Stencil Printing

In one embodiment, in the stencil printing method, a metal mask having at least one opening is used. The shape of the opening may be tapered, that is, a tapered shape in which, when the mask is placed on a substrate, the width of the opening becomes gradually smaller from the paste-filling side (upper part) of the mask to the substrate-contact side (lower part), or may be a non-tapered shape in which the upper part of the opening has the same distance as the lower part of the opening.

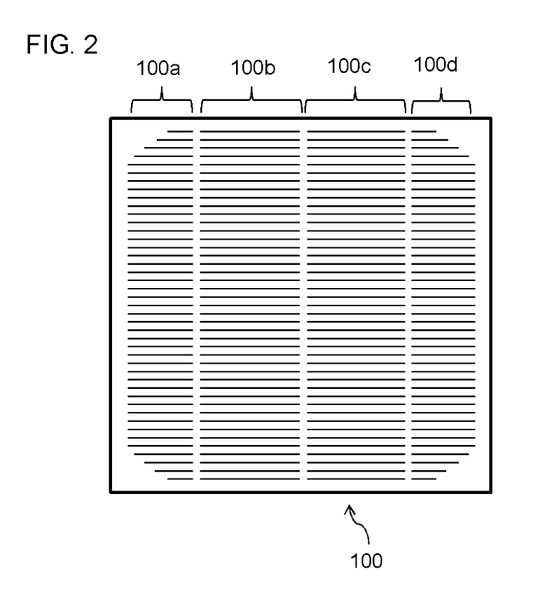

One example of the metal mask is shown schematically in FIG. 2, but the metal mask which can be used in the present invention is not limited to the example.

Metal mask 100 in FIG. 2 has four blocks, block 100 a, block 100 b, block 100 c and block 100 d. Each of blocks has a plurality of parallel lines which actually represent parallel linear openings for stencil printing so that the conductive paste can be applied onto the substrate through the openings.

The number, width and pitch of obtainable patterns by stencil printing are determined according to, for example the shape and arrangement of these openings in metal mask 100. The thickness and opening width of the metal mask 100 are especially designed so that the obtainable pattern has desired fineness and a desired aspect ratio, on the basis of the diameter of the ingredients such as conductive powders contained in the paste, the solid content, the viscosity of the paste, etc.

The thickness of the metal mask 100 is from about 0.003 mm to about 0.2 mm in an embodiment. The opening width of parallel lines is from about 10 μm to 200 μm in an embodiment. The metal mask 100 may be, for example, a foil made of a metal such as nickel or stainless steel.

In the stencil printing method, a mask having openings is placed on a substrate, and the conductive paste is applied thereto. During the application, a squeegee or a feed supply head may be used, or the step of forcing the paste out from the opening of the mask to the substrate may be involved.

As to the stencil printing, methods known in the art can be applied. For example, US20140057369 can be referred to.

Firing

The firing may be performed using a conventional infrared belt furnace, but other type of high temperature processing equipment such as an infrared beam furnace can be also used.

The total firing time may be from 20 seconds to 15 minutes when a typical infrared belt furnace is used. The measured peak temperature on the surface of the substrate is 450 to 1000° C. in one embodiment, 650 to 870° C. in another embodiment, and 700 to 800° C. in another embodiment. In another embodiment, the measured temperature on the surface of the substrate can be 10 to 60 seconds at over 400° C. and 2 to 10 seconds at over 600° C. The firing temperature can be measured with a K-type thermocouple attached to the upper surface of the substrate where the aforementioned conductive paste is going to be applied. The temperature profile can be recorded using an environmental data logger such as Datapaq® Furnace Tracker® System, for example.

### P-Type Solar Cell Electrode

The p-type solar cell electrode formed on the p-type emitter can be formed efficiently with a high aspect ratio, a narrow line width (fine line) and low line resistance (ohms/cm). The line width of the electrode is 10 to 100 μm in one embodiment, 20 to 60 μm in another embodiment.

The height of the electrode is 4 to 60 μm in one embodiment, 10 to 35 μm in another embodiment. An aspect ratio (height/width) is 0.4 to 0.6 in one embodiment, 0.37 to 0.55 in another embodiment. In this specification, “aspect ratio” means the value of height/width of the formed electrode, and specific measurement and calculation methods are shown in the Examples given below.

The line resistance (ohms/cm) of the electrode is no more than 0.5 (ohms/cm) in one embodiment, no more than 0.4 (ohms/cm) in another embodiment. A solar cell electrode with such aspect ratio and low line resistance (ohms/cm) can show excellent photoelectric conversion efficiency (%).

### Examples

The present invention is illustrated by, but is not limited to, the following examples.

### Conductive Paste Preparation

Conductive pastes were prepared according to the following procedure by using the following materials.
Conductive powder: Spherical silver (Ag) powder with particle diameter (D50) of 3 μm as determined with a laser scattering-type particle size distribution measuring apparatus.
Aluminum (Al) powder: Spherical aluminum (Al) powder with particle diameter (D50) of 3.5 μm as determined with a laser scattering-type particle size distribution measuring apparatus.
Glass frit: Glass frit containing 60.0 mol % of PbO, 2.0 mol % of SiO₂, 2.0 mol % of Al₂O₃, 36.0 mol % of B₂O₃. The softening point determined by DTA was 380° C.
Organic medium: mixture of 40.3 wt % Butyl Carbitol™ Acetate, 7.5 wt % Butyl Carbitol™, 34.3 wt % Texanol™, 2.9 wt % Ethyl Cellulose, 7.5 wt % Foralyn 110™, and 7.5 wt % additives.
Amide compound: Fatty acid diamide (Thixatrol® Plus from Elementis Specialties Inc.)

The organic medium was mixed with the viscosity modifier for 15 minutes. To enable the uniform dispersion of a small amount of Al powder in the conductive paste, the Ag powder and the Al powder were dispersed in the organic medium separately to mix together afterward. First, the Al powder was dispersed in some of the organic medium and mixed for 15 minutes to prepare an Al slurry. Second, the glass frit was dispersed in the rest of the organic medium and mixed for 15 minutes and then the Ag powder was incrementally added to prepare Ag paste. The mixture was repeatedly passed through a 3-roll mill at progressively increasing pressures from 0 to 400 psi. The gap of the rolls was adjusted to 1 mil.

Then the Ag paste and the Al slurry were mixed together to prepare the conductive paste. Finally additional organic medium or thinners were mixed to adjust the viscosity of the paste. The content of each component are shown in Table 2. The viscosity measured at 10 rpm and 25° C. with a Brookfield HBT viscometer and #14 spindle and a SC4-14/6R utility cup was 655 Pa·s. The degree of dispersion as measured by fineness of line (4th/50%) was 20/10 or less.

### Manufacture of Test Pieces

The conductive paste obtained above was stencil printed onto a SiNₓ layer (passivation layer) with 90 nm average thickness, formed on a p-type emitter of an n-base type mono-silicon substrate (239 cm², 6 inch×6 inch pseudo-square). The stencil mask was a 360 mm-sq. nickel mask (40 μm thickness, manufactured by SONOCOM Co., Ltd.). The nickel mask had a four blocks of parallel line pattern where the 100 lines each having 40 μm width were arranged with fixed pitch of 1.54 mm.

Then the printed conductive paste was dried at 150° C. for 5 min in a convection oven.

Electrodes were then obtained by firing the printed conductive pastes in an IR heating type of belt furnace (CF-7210B, Despatch industry) at peak temperature setting with 885° C. The furnace set temperature of 885° C. corresponded to a measured temperature at the upper surface of the silicon substrate of 754° C. Firing time from furnace entrance to exit was 80 seconds. The firing profile had a ramping rate from 400 to 600° C. in 11 seconds, and the period over 600° C. for 6 seconds. The temperature was measured at the upper surface of the silicon substrate with a K-type thermocouple and recorded using an environmental data logger (Datapaq® Furnace Tracker® System, Model DP9064A, Datapaq Ltd.). The belt speed of the furnace was 550 cpm.

Test Procedure: Aspect Ratio, Line Resistance (ohms/cm), and Efficiency (%))

Aspect Ratio:

The geometrical profiles of sections of the formed electrode were obtained by processing the images captured with a confocal microscope (Lasertech OPTELICS 130C). Both the lateral profile (line width) and the vertical profile (line height) were obtained which are converted to average width and the average cross sectional area, respectively. Then the average height of the line after firing was calculated by (Average height)=(average cross sectional area)/(average width). Then the aspect ratio was calculated as (Average height)/(Average width) with the measured width and height of the formed electrode.

Cell I-V Characteristics

The N-type solar cells produced according to the method described herein will be tested for efficiency with a commercial IV tester (NCT-150AA, NPC Corporation). The Xe Arc lamp in the IV tester simulates the sunlight with a known intensity and spectrum t with air mass value of 1.5 to irradiate the p-type emitter side of the n-base solar cell. The tester will be “four-point probe method” to measure current (I) and voltage (V) at approximately 400 load resistance settings to determine the cell's 1-V curve. The bus bars which will be printed on the p-type emitters, front sides of the cells, will be connected to the multiple probes of the IV tester and the electrical signals will be transmitted through the probes to the data processing computer to obtain solar cell's 1-V characteristics, including the short circuit current, the open circuit voltage, the fill-factor (FF), and the cell efficiency.

Line Resistance (ohms/cm)

A section of the solar cell was cut into a rectangular piece with a constant length (e.g. 20 mm) to eliminate the contribution of the bulbar from the measurement. Cutting was done by hand after scribing the opposite side of the p-type electrode using a commercial laser scriber. Then the resistance of a section of the electrode was measured using two pairs of voltage and current probes attached to the surface of the electrode at a fixed distance (e.g. 1.5 cm). A commercial source meter (Keithley Instruments Model 2400) was used to measure the resistance. The resistance between a 1.5 cm section of all the electrode on the cell (i.e. 100 lines) was measured to obtain a median line resistance value of the formed electrode. Measured values were divided by 1.5 to express the line resistance in the unit of ohms/cm.

TABLE 2

| | | Ex. 1 | | Co. Ex 1 | | Co. Ex 2 | |
|---|---|---|---|---|---|---|---|
| | Ag Powder | 83.7 | wt % | 80.4 | wt % | 81.5 | wt % |
| | Al Powder | 1.6 | wt % | 1.5 | wt % | 1.5 | wt % |
| | Glass frit | 7.4 | wt % | 7.1 | wt % | 7.2 | wt % |
| | Organic medium | 7.3 | wt % | 11.0 | wt % | 9.8 | wt % |
| | Amide | 0.6 | wt % | 0.0 | wt % | 0.0 | wt % |
| **Viscosity(Pa · s) | | 655 | | 290 | | 413 | |
| | Average width | 51.1 | μm | 55.9 | μm | 49.4 | μm |
| | of the electrode | | | | | | |
| | Average height | 21.6 | μm | 14.9 | μm | 15.9 | μm |
| | of the electrode | | | | | | |

| | | | |
|---|---|---|---|
| *Aspect ratio | 0.429 | 0.267 | 0.327 |
| Line resistance | 0.371 | 0.549 | 0.598 |
| (ohms/cm) | | | |

*Aspect ratio is (Average width/Average height) of the formed electrode.
**Viscosity of the conductive paste composition is a value obtained by measurement at 25° C., 10 rpm using a Brookfield HBT viscometer with a #14 spindle and a SC4-14/6R utility cup.

In Comparable Example 1, the paste had a modest viscosity of around 290 Pas and the measured average line width after firing was 55.9 μm, meaning approximately 16 μm wider lines are formed compared to the designed mask opening width of 40 μm. In Comparable Example 2, the paste has higher viscosity of 413 Pas compared to the paste of Comparable Example 1. This resulted in narrower average line width (only about 9 μm wider than the design) and a higher aspect ratio (0.327) than the Comparable Example 1 (0.267). However, the line resistance was high.

In Example 1, the aspect ratio was significantly improved (0.429) and Line resistance was also dramatically improved compared to Comparable 1-2.

We claim:

1. A method of manufacturing a solar cell electrode comprising the steps of:
preparing an N-type solar cell substrate, wherein the N-type solar cell substrate comprises an n-doped semiconductor substrate, a p-type emitter formed on one side of the semiconductor substrate, and a passivation layer formed on the p-type emitter;
stencil printing a conductive paste onto the passivation layer through a printing mask, the conductive paste comprising:
(i) 60 wt % to 95 wt % of a conductive powder,
(ii) 0.4 wt % to 3.0 wt % of an aluminum powder,
(iii) 0.1 wt % to 10 wt % of a glass frit,
(iv) 3 wt % to 30 wt % of an organic medium,
(v) 0.4 wt % to 1.7 wt % of an amide compound,
wherein the wt % are based on the total weight of the conductive paste; and
firing the applied conductive paste to form a solar cell electrode in electric contact with the p-type emitter.

2. The method of claim 1, wherein the glass frit is a lead-free glass frit comprising one or more of oxides selected from the group consisting of boron oxide (B₂O₃), zinc oxide (ZnO), bismuth oxide (Bi₂O₃), silicon oxide (SiO₂), aluminum oxide (Al₂O₃), alkaline-earth metal oxide and alkali metal oxide.

3. The method of claim 1, wherein the glass frit is a lead-containing glass frit comprising lead oxide (PbO) and one or more of oxides selected from the group consisting of boron oxide (B₂O₃), zinc oxide (ZnO), bismuth oxide (Bi₂O₃), silicon oxide (SiO₂), aluminum oxide (Al₂O₃), alkaline-earth metal oxide, and alkali metal oxide.

4. The method of claim 1, wherein the amide compound is a fatty acid amide.

5. The method of claim 4, wherein the fatty acid amide is a fatty acid diamide.

6. The method of claim 5, wherein the fatty acid diamide is represented by the formula: R′—CO—NH—R″—NH—CO—R′, wherein R′ independently represents a substituted or unsubstituted aliphatic chain of a fatty acid, and R″ represents a substituted or unsubstituted alkylene group.

7. The method of claim 1, wherein a width of the solar cell electrode is 20 to 60 μm and a height of the solar cell electrode is 10 to 35 μm.

8. The method of claim 1, wherein an aspect ratio (height/width) of the solar cell electrode is 0.4 to 0.6.

9. The method of claim 1, wherein line resistance (ohms/cm) of the solar cell electrode is no more than 0.4 (ohms/cm).

10. The method of claim 1, wherein peak temperature in the firing step is 700 to 800′C.

11. The method of claim 1, wherein the printing mask is a metal mask.

12. A solar cell electrode manufactured by the method of claim 1.
